(19) United States
(12) Patent Application Publication
(10) Pub. No.: US 2026/0311730 A1
(43) Pub. Date: Oct. 8, 2026

(54) SEMICONDUCTOR DEVICE AND METHOD OF MANUFACTURING SEMICONDUCTOR DEVICE

(71) Applicant: SK hynix Inc., Gyeonggi-do (KR)

(72) Inventor: Seok Hyun LEE, Gyeonggi-do (KR)

(21) Appl. No.: 19/262,107

(22) Filed: Jul. 8, 2025

(30) Foreign Application Priority Data
Apr. 3, 2025 (KR) 10-2025-0043623

(51) Int. Cl. G11C 5/06; H01L 23/00; H10B 41/10; H10B 41/27; H10B 41/40; H10B 43/10; H10B 43/27; H10B 43/40; H10D 80/30

(52) U.S. Cl. CPC G11C 5/063; H10B 41/10; H10B 41/27; H10B 41/40; H10B 43/10; H10B 43/27; H10B 43/40; H10D 80/30; H10W 90/792

(57) ABSTRACT

A semiconductor device includes: a gate structure that includes alternately stacked conductive layers and first insulating layers; a dummy stack adjacent to the gate structure in a first direction and including a first sidewall facing the gate structure, the first sidewall extending in a second direction along a length of the first sidewall and having a repeatedly nonplanar shape, wherein the second direction intersects the first direction; and a second insulating layer located between the gate structure and the dummy stack, wherein the dummy stack is located at a boundary of at least one component of the semiconductor device.

### CROSS-REFERENCE TO RELATED APPLICATION

This application claims priority under 35 U.S.C. § 119 to Korean Patent Application No. 10-2025-0043623 filed on Apr. 3, 2025, which is incorporated herein by reference in its entirety.

### BACKGROUND

### 1. Technical Field

Embodiments of the present disclosure relate to an electronic device, and more particularly, to a semiconductor device and a method of manufacturing the semiconductor device.

### 2. Related Art

The degree of integration of a semiconductor device is mainly determined by an area occupied by a unit memory cell. Recently, as the improvement in the degree of integration of semiconductor devices that are used for forming memory cells in a single layer on a substrate reaches a limit, three-dimensional semiconductor devices for stacking memory cells on a substrate have been proposed. Furthermore, various structures and manufacturing methods have been developed to improve the operational reliability of such a semiconductor device.

### SUMMARY

In an embodiment, a semiconductor device may include: a gate structure including alternately stacked conductive layers and first insulating layers; a dummy stack adjacent to the gate structure in a first direction and including a first sidewall facing the gate structure, the first sidewall extending in a second direction along a length of the first sidewall and having a repeatedly nonplanar shape, wherein the second direction intersects the first direction; and a second insulating layer located between the gate structure and the dummy stack, wherein the dummy stack is located at a boundary of at least one component of the semiconductor device.

In an embodiment, a semiconductor device may include: a first gate structure including alternately stacked first conductive layers and first insulating layers; a second gate structure adjacent to the first gate structure in a first direction and including alternately stacked second conductive layers and second insulating layers; a dummy stack located between the first gate structure and the second gate structure, and including alternately stacked third insulating layers and fourth insulating layers, and including a first sidewall facing the first gate structure, the first sidewall extending in a second direction along a length of the first sidewall and deviating and extending from the second direction in some regions, wherein the second direction intersects the first direction; a peripheral circuit; and a bonding structure located between the peripheral circuit and the dummy stack.

In an embodiment, a method of manufacturing a semiconductor device may include: alternately stacking first material layers and second material layers to form a stack; forming a staircase structure by etching the stack; forming a first sidewall by etching the stack so that the staircase structure is transferred downward; and forming a second sidewall by etching the stack so that the staircase structure and the first sidewall are transferred downward, the second sidewall being spaced apart from the first sidewall in a first direction, wherein at least one of the first sidewall and the second sidewall extends in a second direction along a length of the at least one of the first sidewall and the second sidewall and deviates from the second direction in at least some regions, the second direction intersecting the first direction.

### BRIEF DESCRIPTION OF THE DRAWINGS

The above and other objects, features and advantages of the present disclosure will be more apparent from the following detailed description taken in conjunction with the accompanying drawings:

FIGS. 1A and 1B are diagrams illustrating the structure of a semiconductor device in accordance with an embodiment of the present disclosure.

FIG. 2 is a diagram illustrating the structure of a semiconductor device in accordance with an embodiment of the present disclosure.

FIGS. 3A to 3C are diagrams illustrating the structure of a semiconductor device in accordance with an embodiment of the present disclosure.

FIGS. 4A and 4B are diagrams illustrating the structure of a semiconductor device in accordance with an embodiment of the present disclosure.

FIG. 5 is a diagram illustrating the structure of a semiconductor device in accordance with an embodiment of the present disclosure.

FIG. 6 is a diagram illustrating the structure of a semiconductor device in accordance with an embodiment of the present disclosure.

FIGS. 7A, 8A, 9A, 10A, 11A, 12A, 13A, and 14A and FIGS. 7B, 8B, 9B, 10B, 11B, 12B, 13B, and 14B are diagrams illustrating the structure of a semiconductor device in accordance with an embodiment of the present disclosure.

FIGS. 15A to 15D are diagrams for describing a method of manufacturing a semiconductor device in accordance with an embodiment of the present disclosure.

FIGS. 16A, 17A, 18A, and 19A, FIGS. 16B, 17B, 18B, and 19B, and FIG. 19C are diagrams for describing a method of manufacturing a semiconductor device in accordance with an embodiment of the present disclosure.

FIG. 20 is a diagram illustrating the structure of a semiconductor device in accordance with an embodiment of the present disclosure.

FIG. 21 is a configuration diagram of a semiconductor device in accordance with an embodiment of the present disclosure.

FIG. 22 is a configuration diagram of a semiconductor device in accordance with an embodiment of the present disclosure.

### DETAILED DESCRIPTION

Various embodiments are directed to a semiconductor device having a stable structure and improved characteristics and a method of manufacturing the semiconductor device.

Hereinafter, various embodiments of the present disclosure are described with reference to accompanying drawings. Advantages and features of the present disclosure and methods for implementing them will become apparent with reference to embodiments to be described below in detail together with the accompanying drawings. However, this is not intended to limit the present disclosure to specific embodiments.

The present disclosure may be implemented in various different forms without being limited to an embodiment and should be understood as including various modifications, equivalents, and/or alternatives of embodiments of the present disclosure.

Also, in adding reference numerals to components of each drawing, it should be noted that like components are designated by like numerals even though illustrated on other drawings.

In the specification, the singular forms include plural forms unless otherwise mentioned. The terms “comprises” and/or “comprising”, which are used in the specification, specify the presence of components, steps, operations, and/or elements, but do not preclude the presence or addition of one or more other components, steps, operations, and/or elements.

Herein below, by stacking memory cells in three dimensions, embodiments of the present disclosure provide a capability to improve the degree of integration of a semiconductor device. The embodiments of the present disclosure also provide a semiconductor device having a stable structure and improved reliability.

Hereafter, embodiments in accordance with the technical spirit of the present disclosure will be described with reference to the accompanying drawings.

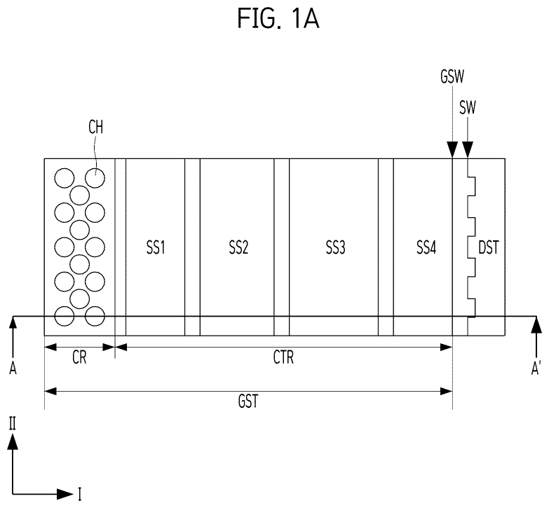

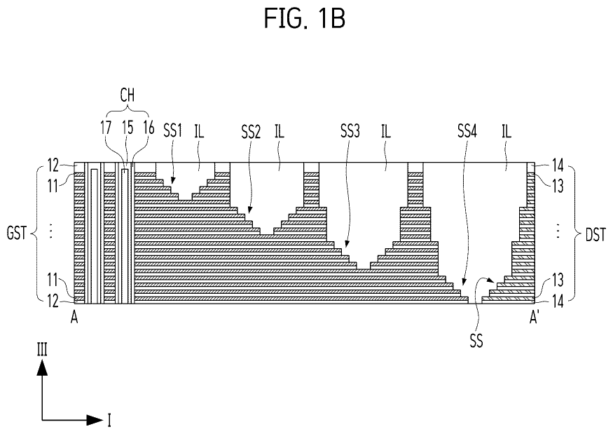

FIGS. 1A and 1B are diagrams illustrating the structure of a semiconductor device in accordance with an embodiment of the present disclosure. FIG. 1B is a cross-sectional view taken along line A-A′ of FIG. 1A.

Referring to FIGS. 1A and 1B, the semiconductor device may include a gate structure GST and a dummy stack DST. The semiconductor device may further include channel structures CH and insulating layers IL.

The gate structure GST may include conductive layers 11 and insulating layers 12 that are alternately stacked. The conductive layers 11 may be a drain select line, word lines, or a source select line. As an example, at least one conductive layer 11 located at the lowermost portion may be a source select line, at least one conductive layer 11 located at the uppermost portion may be a drain select line, and the remaining conductive layers 11 may be word lines.

The gate structure GST may include a cell region CR and a contact region CTR. The cell region CR and the contact region CTR may be adjacent to each other in a first direction I. The cell region CR may be a region where memory cells are stacked. The channel structures CH may be located in the cell region CR, and may be arranged in the first direction I and a second direction II intersecting the first direction I. The channel structures CH may extend in a third direction III through the gate structure GST. The third direction III may be perpendicular to the first direction I and the second direction II. Each of the channel structures CH may include a channel layer 15, a memory layer 16, and an insulating core 17. The memory layer 16 may include at least one of a tunneling layer, a data storage layer, and a blocking layer.

The contact region CTR may be a region where an interconnection structure for applying a bias to the stacked conductive layers 11 is located. The interconnection structure may include a via, a wiring line, and the like. The contact region CTR may include staircase structures SS1 to SS4. Pads of the conductive layers 11 may be defined through the staircase structures SS1 to SS4. According to the staircase structures SS1 to SS4, ends of the respective conductive layers 11 might not be covered by the conductive layers 11 located above the respective conductive layers 11, and regions that are not covered by the conductive layers 11 located above the respective conductive layers 11 may be defined as the pads.

The staircase structures SS1 to SS4 may be located at different levels. In a cross section defined by the first direction I and the third direction III, a second staircase structure SS2 may be located at a lower level than a first staircase structure SS1, a third staircase structure SS3 may be located at a lower level than the second staircase structure SS2, and a fourth staircase structure SS4 may be located at a lower level than the third staircase structure SS3. Insulating layers IL may be filled in (or may fill in) trenches including the staircase structures SS1 to SS4.

The dummy stack DST may be adjacent to the gate structure GST in the first direction I. The insulating layer IL may be filled between the gate structure GST and the dummy stack DST. The dummy stack DST may include first insulating layers 13 and second insulating layers 14 that are alternately stacked. The first insulating layers 13 may be located to correspond to the conductive layers 11, and the second insulating layers 14 may be located to correspond to the insulating layers 12. The first insulating layers 13 may each include a material having a high etching selectivity with respect to the second insulating layers 14. As an example, the first insulating layers 13 may each include nitride, and the second insulating layers 14 may each include oxide.

The dummy stack DST may include a sidewall SW facing the gate structure GST, and may include a staircase structure SS on a portion of the sidewall SW. The staircase structure SS may be located at the same level as the fourth staircase structure SS4. The staircase structure SS and the fourth staircase structure SS4 may have a shape of mirror symmetry.

In a plane defined by the first direction I and the second direction II, the sidewall SW may extend in the second direction II as a main direction (for example, along a length of the sidewall SW), and may deviate from the second direction II in some regions. As an example, the sidewall SW may have a repeatedly bent shape such as an irregular shape, a zigzag shape, or a sawtooth shape. In such a case, the sidewall SW may include angular corners. As an example, the sidewall SW may have a repeatedly curved shape such as a wave shape. In such a case, the sidewall SW may include rounded corners. Unlike the dummy stack DST, a sidewall GSW of the gate structure GST may extend in a straight shape along the second direction II.

According to the structure described above, the sidewall SW of the dummy stack DST has a changed (for example, uneven, nonplanar) shape such as a repeatedly bent (for example, stepped, ridged, ribbed) shape or a repeatedly curved (for example, undulating, sinusoidal, serpentine) shape. Through this, a contact area between the dummy stack DST and the insulating layer IL may be increased, and stress may be dispersed. In addition, the propagation of a crack along the sidewall SW may be reduced.

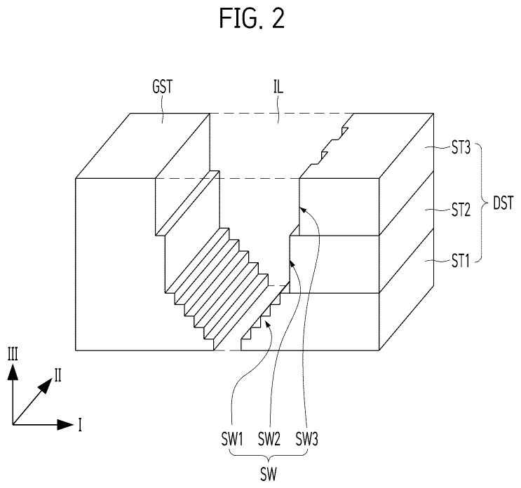

FIG. 2 is a diagram illustrating the structure of a semiconductor device in accordance with an embodiment. Hereinafter, the content overlapping with the previously described content may be omitted.

Referring to FIG. 2, the semiconductor device may include a gate structure GST, a dummy stack DST, and an insulating layer IL. The gate structure GST and the dummy stack DST may be adjacent to each other in the first direction I, and the insulating layer IL may be located between the gate structure GST and the dummy stack DST.

The dummy stack DST may include a first stack ST1, a second stack ST2, and a third stack ST3. In the first direction I, the first stack ST1, the second stack ST2, and the third stack ST3 may have different widths. As an example, the second stack ST2 may be located on the first stack ST1, and may have a smaller width than the first stack ST1. The third stack ST3 may be located on the second stack ST2, and may have a smaller width than the second stack ST2.

The dummy stack DST may include a sidewall SW facing the gate structure GST. The sidewall SW may include a first sidewall SW1, a second sidewall SW2, and a third sidewall SW3. The first stack ST1 includes the first sidewall SW1 facing the gate structure GST. In a cross section defined by the first direction I and the third direction III, the first sidewall SW1 may include a staircase structure. The second stack ST2 includes the second sidewall SW2 facing the gate structure GST. The second sidewall SW2 might not include a staircase structure. The third stack ST3 includes the third sidewall SW3 facing the gate structure GST. The third sidewall SW3 might not include a staircase structure. The first sidewall SW1, the second sidewall SW2, and the third sidewall SW3 may be spaced apart from each other in the first direction I.

In a plane defined by the first direction I and the second direction II, the sidewall SW may extend in the second direction II as a main direction (for example, along a length of the sidewall SW), and may deviate from the second direction II in some regions (for example, extending in a direction different from the second direction). At least one of the first to third sidewalls SW1 to SW3 may have such a changed shape. As an example, the first sidewall SW1 and the second sidewall SW2 may each have a straight shape in which they extend along the second direction II, and the third sidewall SW3 may have a changed shape.

According to the structure described above, the dummy stack DST may include a plurality of sub-stacks, and sidewalls of the sub-stacks may be adjacent to each other in the first direction I. In addition, at least a portion of the sidewall SW of the dummy stack DST may have a changed shape. Through this, the changed (or nonplanar) shape may be selectively applied to a sidewall of the dummy stack DST at a level at which stress is concentrated and/or a level at which a crack (or disruption, weakness, structural defect) is concentrated. Accordingly, a contact area between the dummy stack DST and the insulating layer IL at the selected level may be increased, and the propagation of the crack may be reduced.

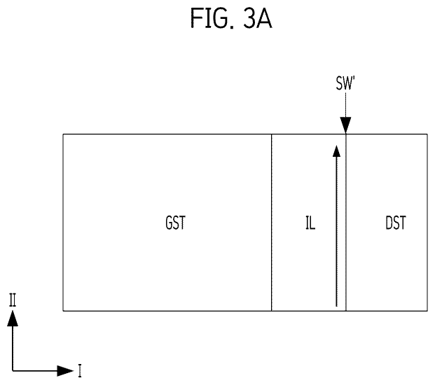

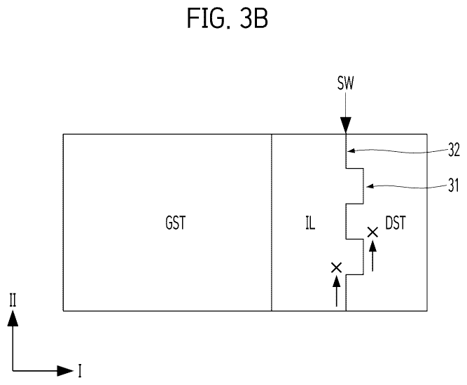

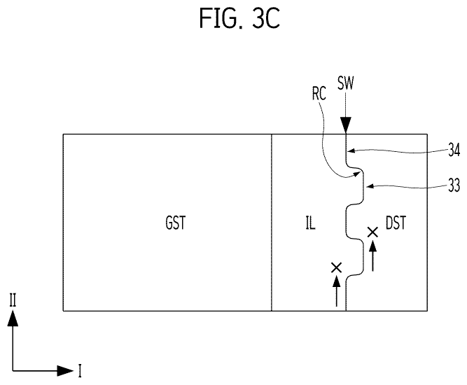

FIGS. 3A to 3C are diagrams illustrating the structure of a semiconductor device in accordance with an embodiment. Hereinafter, the content overlapping with the previously described content may be omitted.

Referring to FIGS. 3A to 3C, the semiconductor device may include a gate structure GST, a dummy stack DST, and an insulating layer IL. The gate structure GST and the dummy stack DST may be adjacent to each other in the first direction I, and the insulating layer IL may be located between the gate structure GST and the dummy stack DST.

A sidewall SW or SW′ of the dummy stack DST may be in contact with the insulating layer IL. An interface between the sidewall SW or SW′ and the insulating layer IL may be vulnerable to stress. In a process of manufacturing the semiconductor device, stress may be induced due to a void, shrinkage of a layer, and the like, and a defect such as a crack may occur due to the stress. The crack may propagate along the interface between the sidewall SW or SW′ and the insulating layer IL.

Referring to FIG. 3A, the sidewall SW′ of the dummy stack DST extends in a straight shape along the second direction II. In such a case, the crack may propagate in the second direction II along the sidewall SW′.

Referring to FIG. 3B, the sidewall SW of the dummy stack DST has a changed shape. The sidewall SW may extend in the second direction II as a main direction, and may deviate from the second direction II in some regions. As an example, the sidewall SW may have a repeatedly bent shape such as an irregular shape, a zigzag shape, or a sawtooth shape. The sidewall SW may include concave portions 31 and convex portions 32, and as the concave portions 31 and the convex portions 32 are alternately repeated, the sidewall SW may include portions deviating and extending in the first direction I. Here, each of the concave portion 31 and the convex portion 32 is not limited to having a rectangular shape, and may have a shape such as a polygonal shape, a circular shape, or an elliptical shape. Because the sidewall SW includes portions deviating and extending from the second direction II as described above, the propagation of the crack may be stopped by the corresponding portions. Accordingly, even though the crack is induced, the propagation of the crack along the second direction II may be reduced.

Referring to FIG. 3C, the sidewall SW of the dummy stack DST has a changed shape. The sidewall SW may extend in the second direction II as a main direction, and may deviate from the second direction II in some regions. As an example, the sidewall SW may have a repeatedly curved shape such as a wave shape. The sidewall SW may include concave portions 33 and convex portions 34. Each of the concave portions 33 and the convex portions 34 may include a rounded corner RC. During a manufacturing process, the insulating layer IL may be formed by depositing an insulating material on the shape-changed sidewall SW of the dummy stack DST. When the sidewall SW includes angled corners, a deposition profile of the insulating material may deteriorate, which may cause a crack. Accordingly, by forming the sidewall SW so that portions deviating and extending from the second direction II include the rounded corners RC, embodiments of the present disclosure improve the deposition profile of the insulating material and reduce the induction of the crack(s).

According to the structure described above, the dummy stack DST may include the shape-changed sidewall SW. Accordingly, a contact area between the dummy stack DST and the insulating layer IL may be increased, and stress may be dispersed. In addition, the propagation of the crack along the sidewall SW may be reduced.

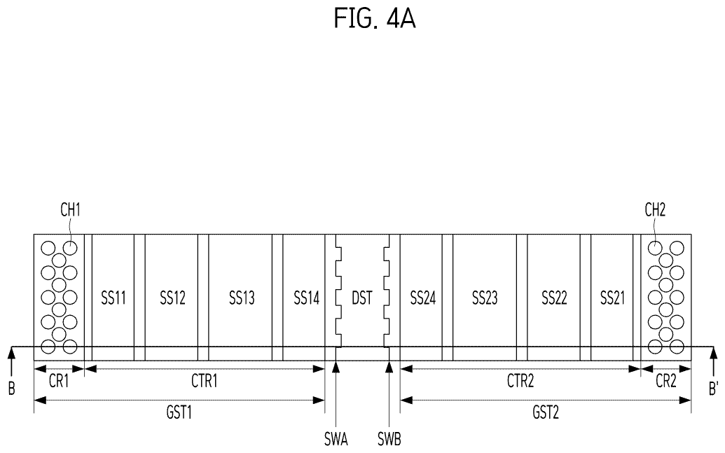

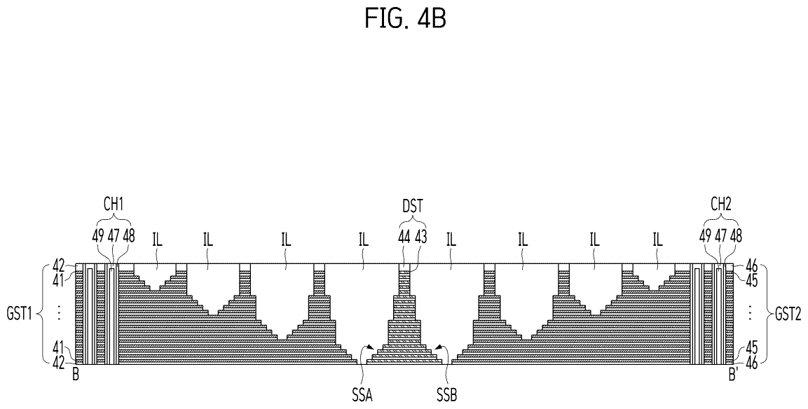

FIGS. 4A and 4B are diagrams illustrating the structure of a semiconductor device in accordance with an embodiment. FIG. 4B is a cross-sectional view taken along line B-B′ of FIG. 4A. Hereinafter, the content overlapping with the previously described content may be omitted.

Referring to FIGS. 4A and 4B, the semiconductor device may include a first gate structure GST1, a second gate structure GST2, and a dummy stack DST. The semiconductor device may further include first channel structures CH1, second channel structures CH2, and insulating layers IL. The first gate structure GST1 and the second gate structure GST2 may be adjacent to each other in the first direction I. The dummy stack DST may be located between the first gate structure GST1 and the second gate structure GST2. Each of the first and second channel structures CH1 and CH2 may include a channel layer 47, a memory layer 48, and an insulating core 49.

The first gate structure GST1 may include first conductive layers 41 and first insulating layers 42 that are alternately stacked. The first gate structure GST1 may include a first cell region CR1 and a first contact region CTR1. The first channel structures CH1 may extend through the first gate structure GST1 in the first cell region CR1. The first contact region CTR1 may include first staircase structures SS11 to SS14. The insulating layers IL may be filled in the first staircase structures SS11 to SS14.

The second gate structure GST2 may include second conductive layers 45 and second insulating layers 46 that are alternately stacked. The second gate structure GST2 may include a second cell region CR2 and a second contact region CTR2. The second channel structures CH2 may extend through the second gate structure GST2 in the second cell region CR2. The second contact region CTR2 may include second staircase structures SS21 to SS24. The insulating layers IL may be filled in the second staircase structures SS21 to SS24.

The dummy stack DST may be adjacent to the first gate structure GST1 and the second gate structure GST2 in the first direction I. The insulating layers IL may be filled between the first and second gate structures GST1 and GST2 and the dummy stack DST. The dummy stack DST may include third insulating layers 43 and fourth insulating layers 44 that are alternately stacked.

The dummy stack DST may include a first sidewall SWA facing the first gate structure GST1 and a second sidewall SWB facing the second gate structure GST2. The dummy stack DST may include a staircase structure SSA on a portion of the first sidewall SWA, and may include a staircase structure SSB on a portion of the second sidewall SWB.

At least one of the first sidewall SWA and the second sidewall SWB may have a changed shape. In a plan view, the first sidewall SWA may extend in the second direction II as a main direction, and may deviate from the second direction II in some regions. The second sidewall SWB may extend in the second direction II as a main direction, and may deviate from the second direction II in some regions. The first sidewall SWA and the second sidewall SWB may have the same shape or different shapes. The first sidewall SWA and the second sidewall SWB may have a symmetrical shape or an asymmetrical shape. Each of the first sidewall SWA and the second sidewall SWB may have an irregular shape, a zigzag shape, a sawtooth shape, a wave shape, or a combination thereof.

According to the structure described above, at least one of the first sidewall SWA and the second sidewall SWB of the dummy stack DST has the changed shape. Through this, a contact area between the dummy stack DST and the insulating layer IL may be increased, and stress may be dispersed. In addition, the propagation of a crack along the sidewall SW may be reduced.

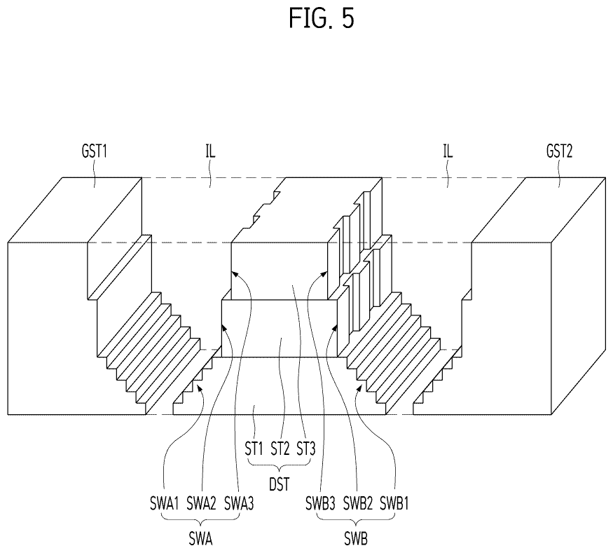

FIG. 5 is a diagram illustrating the structure of a semiconductor device in accordance with an embodiment. Hereinafter, the content overlapping with the previously described content may be omitted.

Referring to FIG. 5, the semiconductor device may include a first gate structure GST1, a second gate structure GST2, a dummy stack DST, and insulating layers IL. The dummy stack DST may be located between the first gate structure GST1 and the second gate structure GST2. The insulating layer IL may be located between the first gate structure GST1 and the dummy stack DST, and the insulating layer IL may be located between the second gate structure GST2 and the dummy stack DST.

The dummy stack DST may include a first stack ST1, a second stack ST2, and a third stack ST3. The first stack ST1 may include a first sidewall SWA1 facing the first gate structure GST1 and a first sidewall SWB1 facing the second gate structure GST2. The second stack ST2 may include a second sidewall SWA2 facing the first gate structure GST1 and a second sidewall SWB2 facing the second gate structure GST2. The third stack ST3 may include a third sidewall SWA3 facing the first gate structure GST1 and a third sidewall SWB3 facing the second gate structure GST2.

At least a portion of a sidewall SWA of the dummy stack DST may have a changed shape. At least one of the first to third sidewalls SWA1 to SWA3 may have a changed shape. At least a portion of a sidewall SWB of the dummy stack DST may have a changed shape. At least one of the first to third sidewalls SWB1 to SWB3 may have a changed shape. The sidewall SWA and the sidewall SWB may have the same shape or different shapes. The sidewall SWA and the sidewall SWB may have a symmetrical shape or an asymmetrical shape.

According to the structure described above, the dummy stack DST may include a plurality of sub-stacks, and at least some of sidewalls of the sub-stacks may have a changed shape. Through this, a contact area between the dummy stack DST and the insulating layer IL at a selected level may be increased, and stress may be dispersed. In addition, the propagation of cracks along the sidewalls SWA and SWB at the selected level may be reduced.

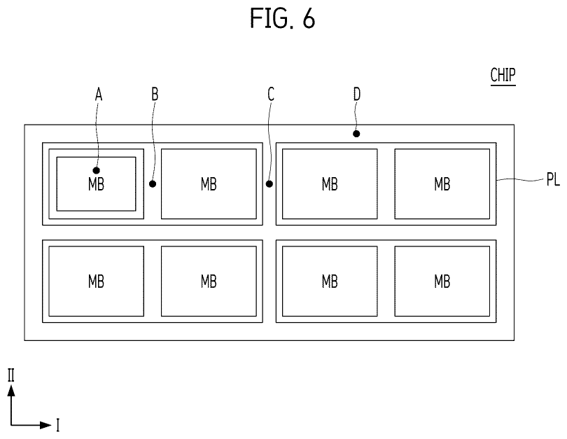

FIG. 6 is a diagram illustrating the structure of a semiconductor device in accordance with an embodiment.

Referring to FIG. 6, a chip CHIP may be a semiconductor chip, and may include a plurality of memory planes PL arranged in the first direction I and the second direction II. As an example, the memory planes PL may be arranged in a matrix form. The respective memory planes PL may operate independently, and may perform different operations in memory plane units. As an example, a first memory plane and a second memory plane may share an output circuit with each other, and may include the remaining components independently. The memory plane PL may include a plurality of memory blocks MB, and the memory block MB may be a unit of an erase operation. As an example, the memory plane PL may include two or more memory blocks MB arranged in the first direction I. Each of the memory blocks may include a plurality of pages, and each of the pages may be a unit of a program/read operation.

Regions A to D represent boundary regions of components of the semiconductor device. The component may be the memory block MB, the memory plane PL or the chip CHIP. The dummy stack DST may be located at the boundary of such a component. Region A represents the inside of the memory block MB. As an example, region A may be a region in which a dummy stack DST is located between a first gate structure GST1 and a second gate structure GST2 and the dummy stack DST and an insulating layer IL are in contact with each other. Region B represents a boundary between the memory blocks MB, region C represents a boundary between the memory planes PL, and region D represents an edge of the chip CHIP. As an example, regions B to D may be regions in which the gate structure GST and the dummy stack DST face each other and the dummy stack DST and the insulating layer IL are in contact with each other.

Regions A to D represent regions in which cracks are likely to occur during the manufacturing process of the semiconductor device. The cracks may propagate along an interface between the dummy stack DST and the insulating layer IL located in regions A to D. Accordingly, as described above with reference to FIGS. 1A to 5, by changing the shape of the sidewall of the dummy stack DST, embodiments of the present disclosure stop (for example, prevent) the propagation of the cracks occurring in regions A to D.

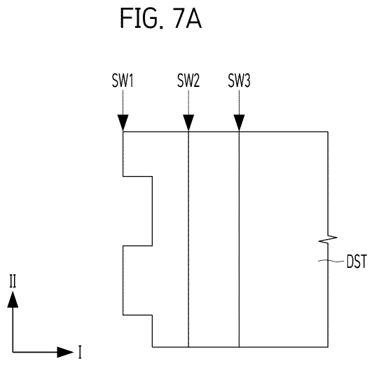

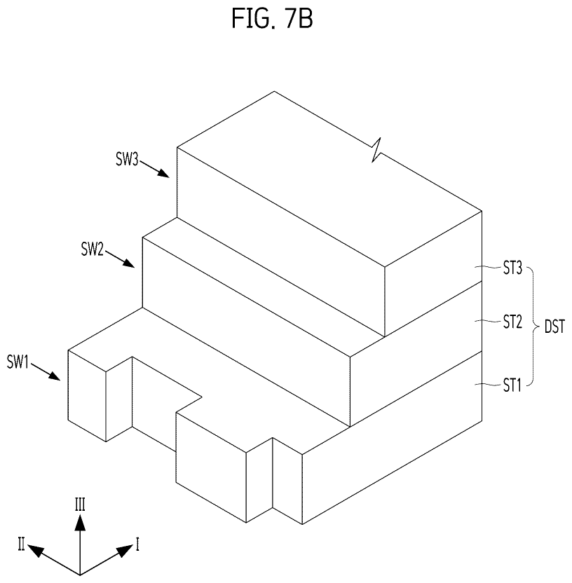

FIGS. 7A, 8A, 9A, 10A, 11A, 12A, 13A, and 14A and FIGS. 7B, 8B, 9B, 10B, 11B, 12B, 13B, and 14B are diagrams illustrating the structure of a semiconductor device in accordance with an embodiment. FIGS. 7A, 8A, 9A, 10A, 11A, 12A, 13A, and 14A are plan views, and FIGS. 7B, 8B, 9B, 10B, 11B, 12B, 13B, and 14B are perspective views. Hereinafter, the content overlapping with the previously described content may be omitted.

Referring to FIGS. 7A to 14A and FIGS. 7B to 14B, the semiconductor device includes a dummy stack DST. The dummy stack DST may include a first stack ST1, a second stack ST2, and a third stack ST3. The dummy stack DST may include a first sidewall SW1, a second sidewall SW2, and a third sidewall SW3. In a cross section, the first sidewall SW1 may or might not include a staircase structure. At least one of the first to third sidewalls SW1 to SW3 may have a changed shape, and the remaining sidewalls may each have a straight shape in which they extend along the second direction II.

For reference, instances in which the dummy stack includes the first to third stacks ST1 to ST3 have been described in each embodiment, but the number of stacks included in the dummy stack may be changed. As an example, in accordance with embodiments of the present disclosure the dummy stack may include four or more stacks.

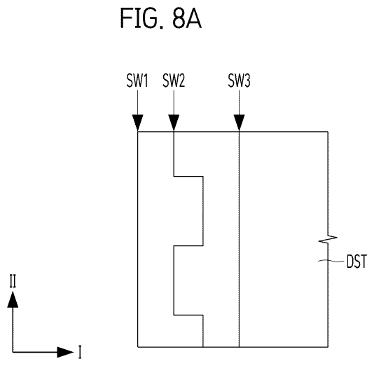

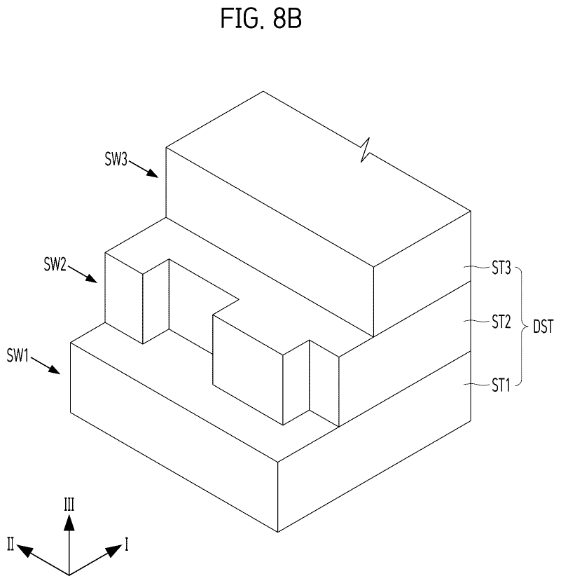

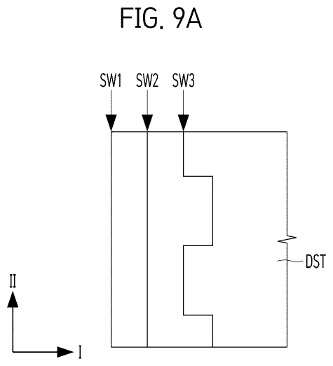

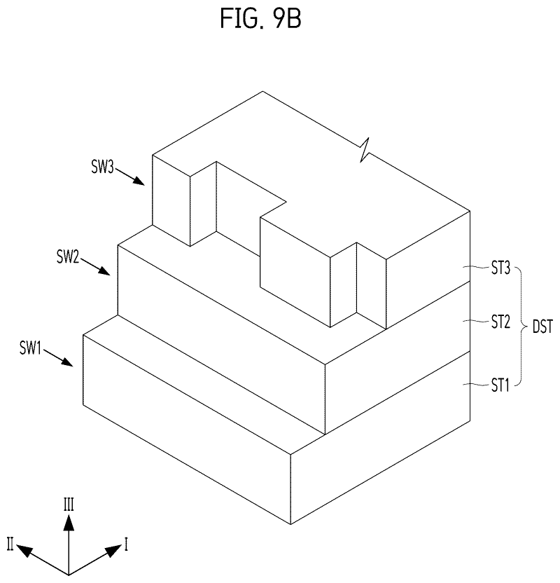

Referring to FIGS. 7A and 7B, the first sidewall SW1 may have a changed (or nonplanar) shape, and the second sidewall SW2 and the third sidewall SW3 may each have a straight (or planar) shape in which they extend along the second direction II. As an example, the first sidewall SW1 may include concave portions and convex portions. Referring to FIGS. 8A and 8B, the second sidewall SW2 may have a changed shape, and the first sidewall SW1 and the third sidewall SW3 may each have a straight shape in which they extend along the second direction II. Referring to FIGS. 9A and 9B, the third sidewall SW3 may have a changed shape, and the first sidewall SW1 and the second sidewall SW2 may each have a straight shape in which they extend along the second direction II.

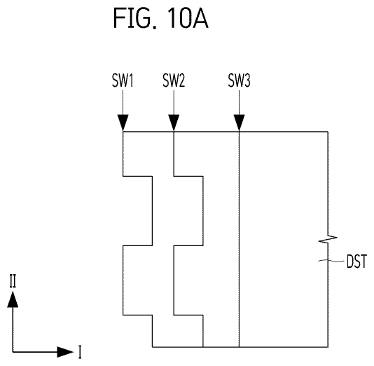

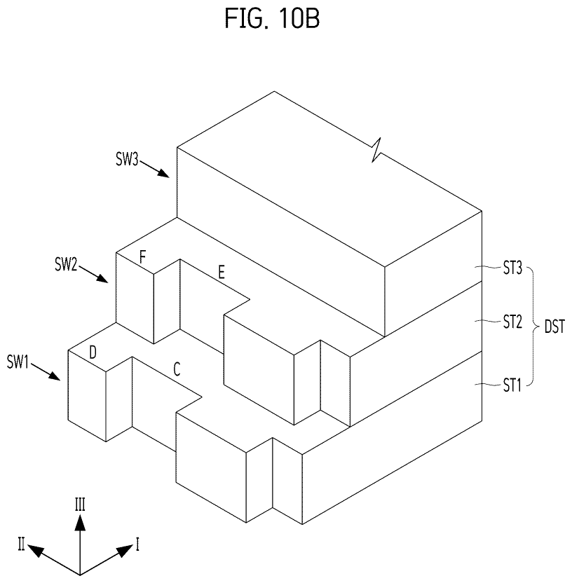

Referring to FIGS. 10A and 10B, the first sidewall SW1 and the second sidewall SW2 may each have a changed shape, and the third sidewall SW3 may have a straight shape in which it extends along the second direction II. As an example, the first sidewall SW1 may include a first concave portion C and a first convex portion D. The second sidewall SW2 may include a second concave portion E and a second convex portion F. The second concave portion E may be located to correspond (for example, align with along a particular direction, such as direction I) to the first concave portion C, and the second convex portion F may be located to correspond to the first convex portion D.

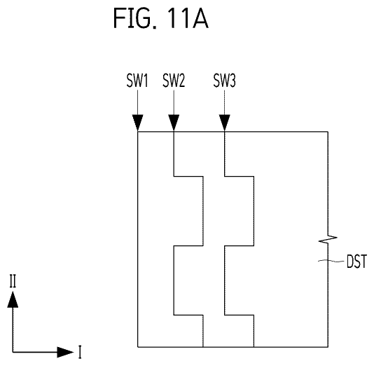

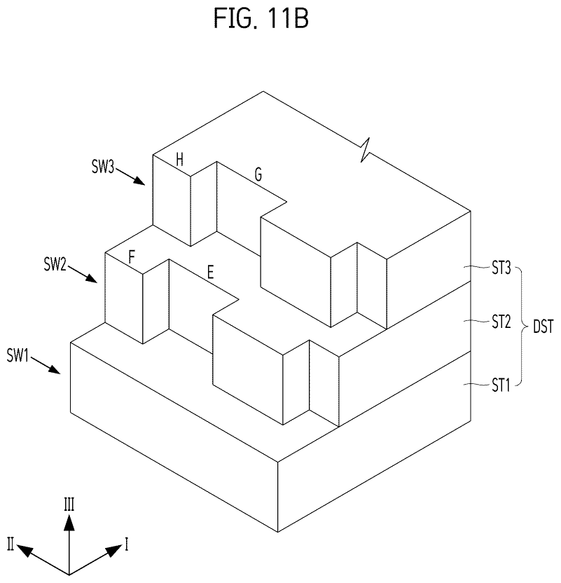

Referring to FIGS. 11A and 11B, the second sidewall SW2 and the third sidewall SW3 may each have a changed shape, and the first sidewall SW1 may have a straight shape in which it extends along the second direction II. As an example, the second sidewall SW2 may include a second concave portion E and a second convex portion F. The third sidewall SW3 may include a third concave portion G and a third convex portion H. The third concave portion G may be located to correspond to the second concave portion E, and the third convex portion H may be located to corresponding to the second convex portion F.

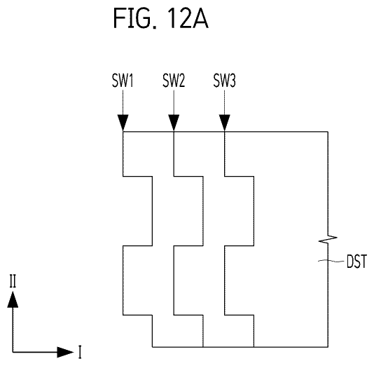

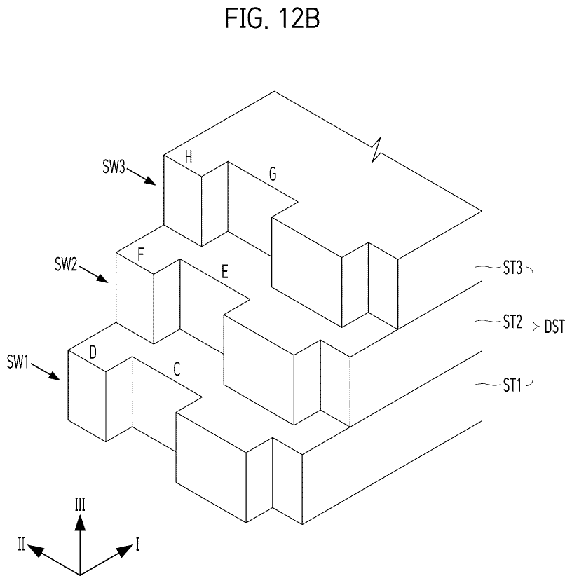

Referring to FIGS. 12A and 12B, the first sidewall SW1, the second sidewall SW2, and the third sidewall SW3 may each have a changed shape. As an example, the first sidewall SW1 may include a first concave portion C and a first convex portion D. The second sidewall SW2 may include a second concave portion E and a second convex portion F. The third sidewall SW3 may include a third concave portion G and a third convex portion H. The first to third concave portion portions C, E, and G may be located to correspond to each other, and the first to third convex portions D, F, and H may be located to correspond to each other.

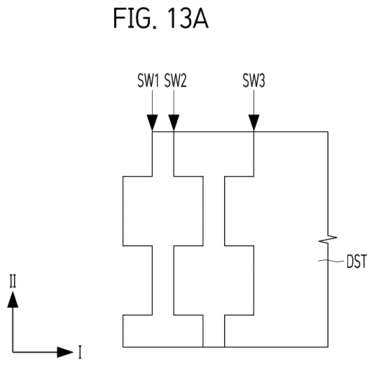

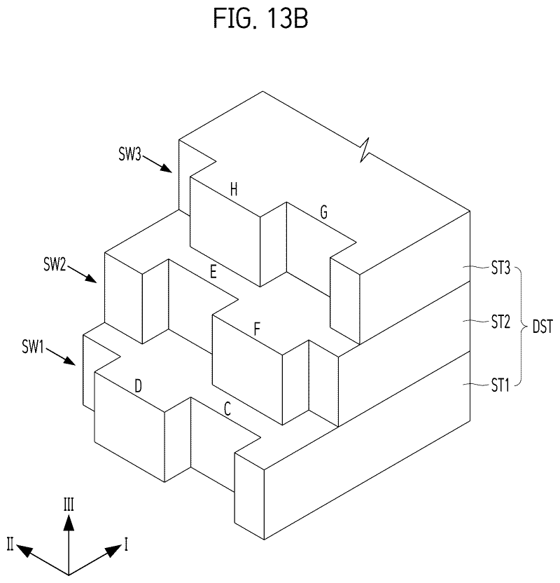

Referring to FIGS. 13A and 13B, the first sidewall SW1, the second sidewall SW2, and the third sidewall SW3 may each have a changed shape. As an example, the first sidewall SW1 may include a first concave portion C and a first convex portion D. The second sidewall SW2 may include a second concave portion E and a second convex portion F. The third sidewall SW3 may include a third concave portion G and a third convex portion H. The first concave portion C and the second convex portion F may correspond to each other, and the first convex portion D and the second concave portion E may correspond to each other. The second concave portion E and the third convex portion H may correspond to each other, and the second convex portion F and the third concave portion G may correspond to each other.

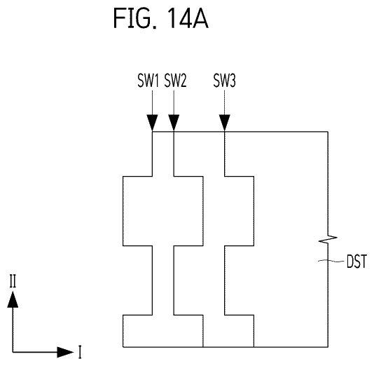

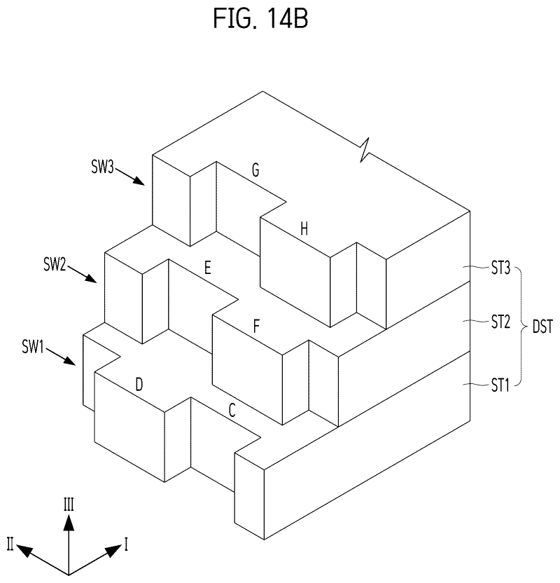

Referring to FIGS. 14A and 14B, the first sidewall SW1, the second sidewall SW2, and the third sidewall SW3 may each have a changed shape. As an example, the first sidewall SW1 may include a first concave portion C and a first convex portion D. The second sidewall SW2 may include a second concave portion E and a second convex portion F. The third sidewall SW3 may include a third concave portion G and a third convex portion H. The first concave portion C and the second convex portion F may correspond to each other, and the first convex portion D and the second concave portion E may correspond to each other. The second concave portion E and the third concave portion G may correspond to each other, and the second convex portion F and the third convex portion H may correspond to each other.

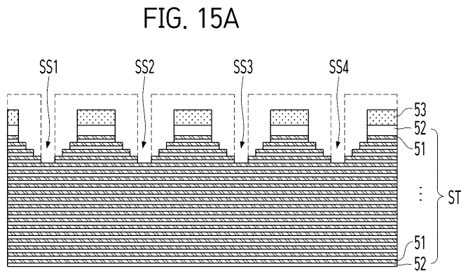

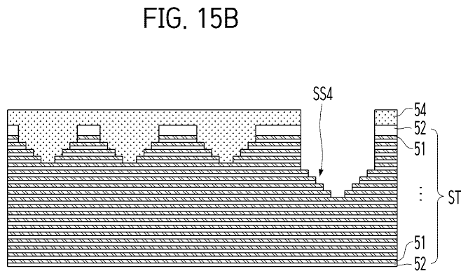

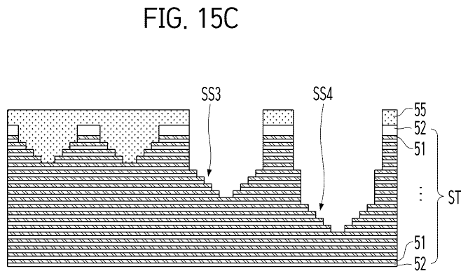

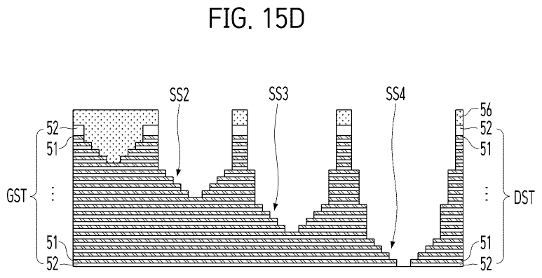

FIGS. 15A to 15D are diagrams for describing a method of manufacturing a semiconductor device in accordance with an embodiment. Hereinafter, the content overlapping with the previously described content may be omitted.

Referring to FIG. 15A, a stack ST including first material layers 51 and second material layers 52 that are alternately stacked may be formed. The stack ST may be used to form a gate structure and a dummy stack in a subsequent process. The first material layers 51 may each include a material having a high etching selectivity with respect to the second material layers 52. As an example, the first material layers 51 may each include a sacrificial material such as a nitride, and the second material layers 52 may each include an insulating material such as an oxide. The first material layers 51 may each include a conductive material such as a polysilicon or metal, and the second material layers 52 may each include an insulating material such as an oxide.

Subsequently, a mask pattern 53 may be formed on the stack ST. The mask pattern 53 may be a photoresist pattern. The stack ST is etched using the mask pattern 53 as an etching barrier, and the mask pattern 53 is reduced. Subsequently, the stack ST is etched using the reduced mask pattern 53 as an etching barrier. First to fourth staircase structures SS1 to SS4 may be formed by repeatedly performing the reducing of the mask pattern 53 and the etching of the stack ST. Subsequently, the mask pattern 53 may be removed.

Referring to FIG. 15B, a mask pattern 54 may be formed on the stack ST. The mask pattern 54 may expose some of the first to fourth staircase structures SS1 to SS4. As an example, the mask pattern 54 may cover the first to third staircase structures SS1 to SS3 and expose the fourth staircase structure SS4. Subsequently, the fourth staircase structure SS4 may be transferred downward by etching the stack ST using the mask pattern 54 as an etching barrier. Subsequently, the mask pattern 54 may be removed.

Referring to FIG. 15C, a mask pattern 55 may be formed on the stack ST. The mask pattern 54 may cover the first staircase structure SS1 and the second staircase structure SS2 and expose the third staircase structure SS3 and the fourth staircase structure SS4. Subsequently, the third staircase structure SS3 and the fourth staircase structure SS4 may be transferred downward by etching the stack ST using the mask pattern 55 as an etching barrier. Subsequently, the mask pattern 55 may be removed.

Referring to FIG. 15D, a mask pattern 56 may be formed on the stack ST. The mask pattern 56 may cover the first staircase structure SS1 and expose the second to fourth staircase structures SS2 to SS4. Subsequently, the second to fourth staircase structure SS2 to SS4 may be transferred downward by etching the stack ST using the mask pattern 56 as an etching barrier. Through this, the first to fourth staircase structures SS1 to SS4 may be located at different levels. In addition, the stack ST may be separated into a gate structure GST and a dummy stack DST. The first material layers 51 of the gate structure GST may be replaced with third material layers including metal in a subsequent process, and the third material layers may be used as gate lines.

According to the method described above, the first to fourth staircase structures SS1 to SS4 located at different levels may be formed in the stack ST. In addition, the stack ST may be separated into the gate structure GST and the dummy stack DST.

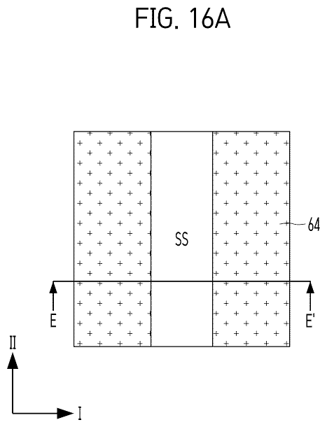

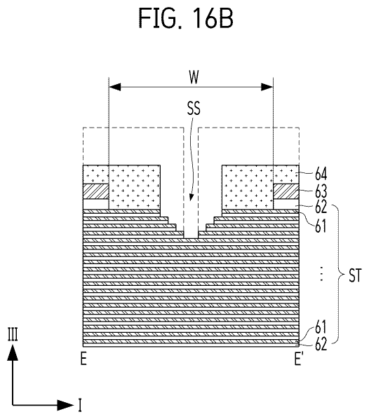

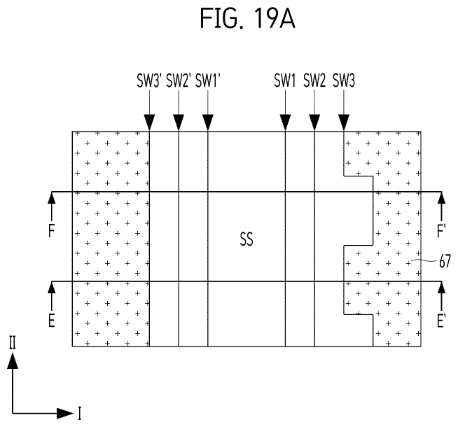

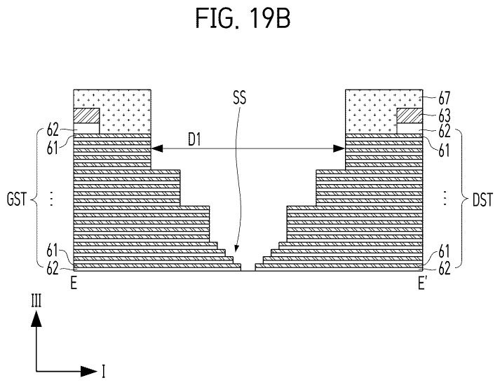

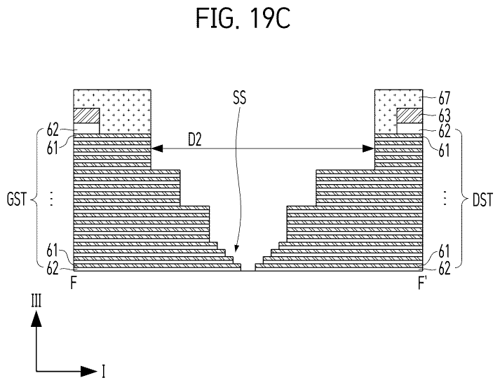

FIGS. 16A, 17A, 18A, and 19A, FIGS. 16B, 17B, 18B, and 19B, and FIG. 19C are diagrams for describing a method of manufacturing a semiconductor device in accordance with an embodiment. FIGS. 16A, 17A, 18A, and 19A are plan views, FIGS. 16B, 17B, 18B, and 19B are cross-sectional views taken along lines E-E′ of FIGS. 16A, 17A, 18A, and 19A, respectively, and FIG. 19C is a cross-sectional view taken along line F-F′ of FIG. 19A. Hereinafter, the content overlapping with the previously described content may be omitted.

Referring to FIGS. 16A and 16B, a stack ST including first material layers 61 and second material layers 62 that are alternately stacked is formed. The first material layers 61 may each include a material having a high etching selectivity with respect to the second material layers 62.

Subsequently, a hard mask pattern 63 may be formed on the stack ST. The hard mask pattern 63 may include an opening exposing a region where a staircase structure is to be formed in a subsequent process. The opening may have a sufficient width W so as to expose locations where sidewalls are to be formed in a process of transferring the staircase structure SS downward.

Subsequently, a mask pattern 64 may be formed on the hard mask pattern 63. The mask pattern 64 may be a photoresist pattern. Subsequently, the stack ST may be etched using the mask pattern 64 and the hard mask pattern 63 as etching barriers. Subsequently, the mask pattern 64 may be reduced, and the stack ST may be etched using the reduced mask pattern 64 and the hard mask pattern 63 as etching barriers. The staircase structure SS may be formed by repeatedly performing the reducing of the mask pattern 64 and the etching of the stack ST. Subsequently, the mask pattern 64 may be removed. For reference, an instance in which one staircase structure SS is formed has been described in the present embodiment, but as described above with reference to FIG. 14A, a plurality of staircase structures may be formed.

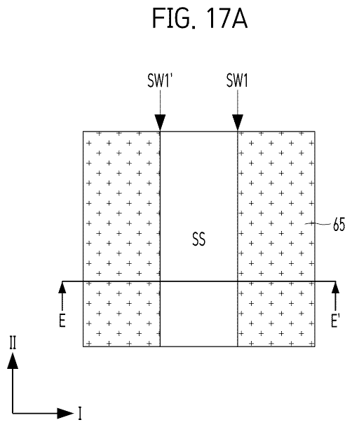

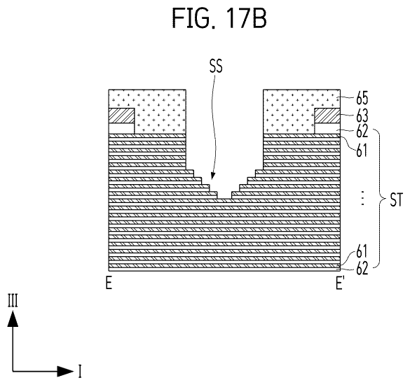

Referring to FIGS. 17A and 17B, a mask pattern 65 may be formed on the stack ST, and the stack ST may be etched using the mask pattern 65 and the hard mask pattern 63 as etching barriers. Through this, the staircase structure SS may be transferred downward, and a first sidewall SW1 and a first sidewall SW1′ may be formed. The first sidewall SW1 may be used to form a portion of a sidewall of a dummy stack, and the first sidewall SW1′ may be used to form a portion of a sidewall of a gate structure. The first sidewall SW1 may have a straight shape or a changed shape, and the first sidewall SW1′ may have a straight shape. Subsequently, the mask pattern 65 may be removed.

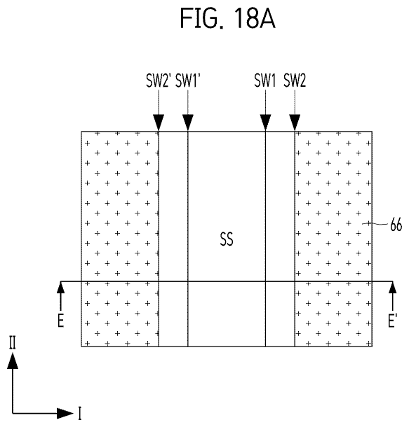

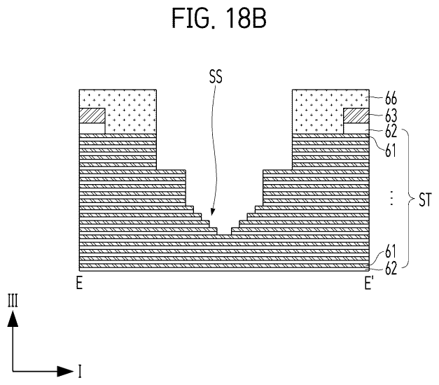

Referring to FIGS. 18A and 18B, a mask pattern 66 may be formed on the stack ST, and the stack ST may be etched using the mask pattern 66 and the hard mask pattern 63 as etching barriers. Through this, the staircase structure SS may be transferred downward, and a second sidewall SW2 and a second sidewall SW2′ may be formed. The second sidewall SW2 may be used to form a portion of the sidewall of the dummy stack, and the second sidewall SW2′ may be used to form a portion of the sidewall of the gate structure. The second sidewall SW2 may have a straight shape or a changed shape, and the second sidewall SW2′ may have a straight shape. Subsequently, the mask pattern 66 may be removed.

Referring to FIGS. 19A to 19C, a mask pattern 67 may be formed on the stack ST, and the stack ST may be etched using the mask pattern 67 and the hard mask pattern 63 as etching barriers. The staircase structure SS may be transferred downward, and a third sidewall SW3 and a third sidewall SW3′ may be formed. Through this, a dummy stack DST including the first to third sidewalls SW1 to SW3 may be formed, and a gate structure GST including the first to third sidewalls SW1′ to SW3′ may be formed. Subsequently, the mask pattern 67 may be removed. The third sidewall SW3 may have a straight shape or a changed shape, and the third sidewall SW3′ may have a straight shape.

As an example, the third sidewall SW3 may have an irregular shape, and the third sidewall SW3′ may have a straight shape. A distance between the third sidewall SW3 and the third sidewall SW3′ may be changed depending on a shape of the third sidewall SW3. Referring to FIG. 19B, the third sidewall SW3 and the third sidewall SW3′ may be spaced apart from each other by a first distance D1. Referring to FIG. 19C, the third sidewall SW3 and the third sidewall SW3′ may be spaced apart from each other by a second distance D2 greater than the first distance D1.

Subsequently, an insulating layer may be formed on the first to third sidewalls SW1 to SW3 and the first to third sidewalls SW1′ to SW3′. The insulating layer may be formed between the gate structure GST and the dummy stack DST. Subsequently, a first wafer including the gate structure GST, the dummy stack DST, and the insulating layer and a second wafer including a peripheral circuit may be bonded to each other.

According to the method described above, the gate structure GST and the dummy stack DST may be formed by separating the stack ST. The sidewalls SW1′ to SW3′ of the gate structure GST and the sidewalls SW1 to SW3 of the dummy stack DST may be formed using the mask patterns 65 to 67, and the sidewalls SW1′ to SW3′ of the gate structure GST and the sidewalls SW1 to SW3 of the dummy stack DST may have different shapes. The first to third sidewalls SW1′ to SW3′ of the gate structure GST may each have a straight shape, and at least one of the first to third sidewalls SW1 to SW3 of the dummy stack DST may have a changed shape. Accordingly, a contact area between the dummy stack DST and the insulating layer may be increased, and the propagation of a crack may be reduced.

In a process of bonding the first wafer and the second wafer to each other, stress and a crack may be induced, and may be concentrated on an interface between the dummy stack DST and the insulating layer IL. Accordingly, the stress may be dispersed and the propagation of the crack may be reduced, through the shape-changed sidewall of the dummy stack DST.

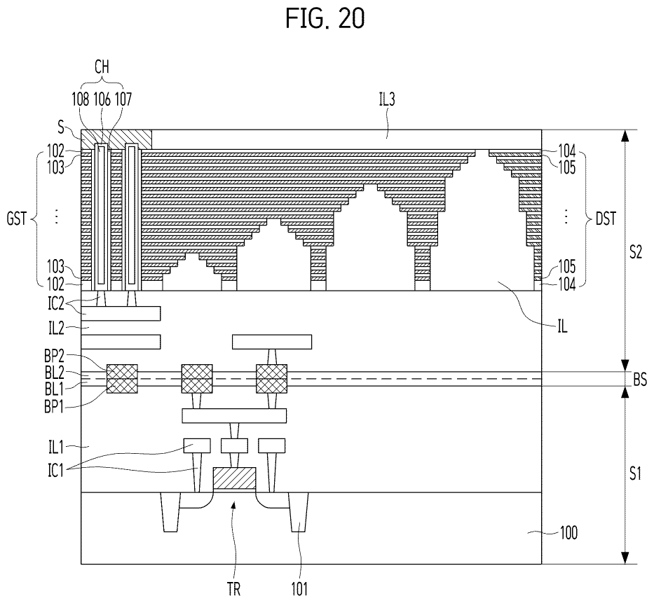

FIG. 20 is a diagram illustrating the structure of a semiconductor device in accordance with an embodiment. Hereinafter, the content overlapping with the previously described content may be omitted.

Referring to FIG. 20, the semiconductor device may include a first semiconductor structure S1, a second semiconductor structure S2, and a bonding structure BS located between the first semiconductor structure S1 and the second semiconductor structure S2. The first semiconductor structure S1 and the second semiconductor structure S2 may be formed using separate wafers. The first semiconductor structure S1 may be formed using a first wafer including a peripheral circuit, and at least a portion of the second semiconductor structure S2 may be formed using a second wafer including a memory cell array. By bonding the first wafer and the second wafer to each other, the bonding structure BS may be formed, and the first semiconductor structure S1 and the second semiconductor structure S2 may be electrically connected to each other through the bonding structure BS.

The first semiconductor structure S1 may include a substrate 100, a transistor TR, a first interconnection structure IC1, and a first interlayer insulating layer IL1. An active region may be defined by an element isolation layer 101 in the substrate 100, and the transistor TR may be located in the active region. The transistor TR may belong to the peripheral circuit. The peripheral circuit may include a row decoder, a page buffer, a logic circuit, an input/output circuit, and the like.

The first interconnection structure IC1 may be located in the first interlayer insulating layer IL1, and may include a via, a wiring line, and the like. The first interconnection structure IC1 may be electrically connected to the peripheral circuit, and may be electrically connected to the transistor TR.

The second semiconductor structure S2 may include a source structure S, a gate structure GST, a dummy stack DST, a channel structure CH, insulating layers IL, a second interconnection structure IC2, a second interlayer insulating layer IL2, and a third interlayer insulating layer IL3. The source structure S may be located above or below the gate structure GST. The source structure S may include a conductive material such as polysilicon or metal. The third interlayer insulating layer IL3 may be located above the gate structure GST and the dummy stack DST.

The gate structure GST may include conductive layers 103 and insulating layers 102 that are alternately stacked. The conductive layers 103 may be gate lines such as a source select line, a drain select line, and word lines. The channel structure CH may extend through the gate structure GST, and may be connected to the source structure S. The channel structure CH may include a channel layer 106, a memory layer 107, and an insulating core 108.

The dummy stack DST may include first insulating layers 105 and second insulating layers 104 that are alternately stacked. The dummy stack DST may include a sidewall facing the gate structure GST, and may have a changed shape in at least a portion of the sidewall. As an example, the sidewall may have an irregular shape. Through this, a contact area between the dummy stack DST and the insulating layer IL may be increased, and the propagation of a crack may be reduced.

The second interconnection structure IC2 may be located in the second interlayer insulating layer IL2, and may include a via, a wiring line, and the like. The second interconnection structure IC2 may be electrically connected to the channel structure CH, the gate structure GST, and the like.

The bonding structure BS may include a first bonding layer BL1, a second bonding layer BL2, a first bonding pad BP1, and a second bonding pad BP2. The first bonding layer BL1 and the second bonding layer BL2 may be in contact with each other, and the first bonding pad BP1 and the second bonding pad BP2 may be in contact with each other. The first bonding layer BL1 and the second bonding layer BL2 may each include Silicon Carbonitride (SiCN), tetra ethyl ortho silicate (TEOS), or the like. The first bonding pad BP1 may be electrically connected to the first interconnection structure IC1, and the second bonding pad BP2 may be electrically connected to the second interconnection structure IC2. The memory cell array and the peripheral circuit may be electrically connected to each other through the first bonding pad BP1 and the second bonding pad BP2.

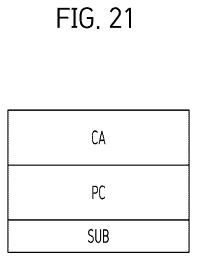

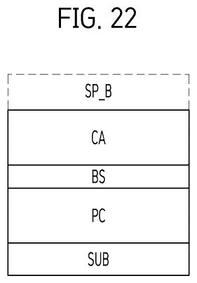

The structure and the manufacturing method according to the above-described embodiments may be applied to semiconductor devices of various structures. FIGS. 21 and 22 illustrate a schematic configuration of a semiconductor device to which the above-described embodiments are applicable.

FIG. 21 is a configuration diagram of a semiconductor device according to an embodiment of the present disclosure.

Referring to FIG. 20, the semiconductor device may include a substrate SUB, a peripheral circuit PC, and a memory cell array CA. Here, the peripheral circuit PC and the memory cell array CA may be formed on the same substrate.

The substrate SUB may be made of or include a semiconductor material. In an embodiment, the semiconductor material may include at least one of a group IV semiconductor, a group III-V compound semiconductor, and a group II-VI compound semiconductor. Here, the group IV semiconductor may include single crystal silicon (Si), polycrystalline silicon, germanium (Ge), or silicon germanium (SiGe). The group III-V compound semiconductor may include gallium arsenide (GaAs), gallium nitride (GaN), gallium phosphide (GaP), gallium arsenide phosphide (GaAsP), gallium indium arsenide phosphide (GaInAsP), aluminum arsenide (AlAs), aluminum gallium (AlGa), indium phosphide (InP), indium antimonide (InSb), or indium gallium arsenide (InGaAs). The group II-VI compound semiconductor may include zinc sulfide (ZnS), zinc oxide (ZnO), or cadmium sulfide (CdS).

The substrate SUB may include a dielectric layer. The substrate SUB may be a silicon-on-insulator (SOI) substrate, a germanium-on-insulator (GeOI) substrate, or a glass substrate. The substrate SUB may include an organic material. In an embodiment, the substrate SUB may include graphene.

The substrate SUB may be a bulk wafer or an epitaxial layer grown in a selective epitaxial growth (SEG) method. The substrate SUB may be a layer formed in a metal induced lateral crystallization (MILC) method and may partially include metal. The substrate SUB may have a single crystalline, polycrystalline, or amorphous state. The substrate SUB may include an impurity of group II, group III, group IV, group V, or group VI. In an embodiment, the substrate SUB may include an n-well region doped with an n-type impurity and/or a p-well region doped with a p-type impurity.

The peripheral circuit PC may be disposed between the substrate SUB and the memory cell array CA. The peripheral circuit PC may include a row decoder, a column decoder, a page buffer, a logic circuit, a control circuit, a sense amplifier, an input/output circuit, and the like. In an embodiment, the peripheral circuit PC may include an NMOS transistor, a p-channel Metal-Oxide-Semiconductor (PMOS) transistor, a resistor, a capacitor, and the like. The peripheral circuit PC may further include an interconnection structure. The interconnection structure may be used as a path for transferring an operation voltage, and may include a contact plug, a line, and the like.

The memory cell array CA may include memory cells. In an embodiment, the memory cell array CA may include memory strings connected between a source line and a bit line, and each memory string may include stacked memory cells. In an embodiment, the memory cell array CA may include memory cells connected between a word line and a bit line. The memory cell array CA may further include an interconnection structure.

FIG. 22 is a configuration diagram of a semiconductor device according to an embodiment of the present disclosure.

Referring to FIG. 22, the semiconductor device may include a substrate SUB, a peripheral circuit PC, a bonding structure BS, and a memory cell array CA. Here, the peripheral circuit PC and the memory cell array CA may be respectively formed on separate substrates and then bonded. The semiconductor device may further include a support base SP_B.

The substrate SUB may be used as a support in a process of forming the peripheral circuit PC. The support base SP_B may be used as a support in a process of forming the memory cell array CA. In an embodiment, after respectively manufacturing a first wafer including the memory cell array CA and a second wafer including the peripheral circuit PC, the first wafer and the second wafer may be electrically connected by the bonding structure BS. After bonding, at least a portion of the support base SP_B of the first wafer may be removed. The support base SP_B may be completely removed or may partially remain on the memory cell array CA.

The support base SP_B may be a semiconductor substrate, an insulating substrate, a silicon-on-insulator (SOI) substrate, a germanium-on-insulator (GeOI) substrate, or the like. The support base SP_B may be a bulk wafer, an epitaxial layer grown in a selective epitaxial growth (SEG) method, or a layer formed in a metal induced lateral crystallization (MILC) method. The support base SP_B may have a single crystalline, polycrystalline, or amorphous state. The support base SP_B may include an impurity of group II, group III, group IV, group V, or group VI.

The bonding structure BS may be for connecting the memory cell array CA and the peripheral circuit PC. In an embodiment, the memory cell array CA and the peripheral circuit PC may be bonded in a wafer-on-wafer bonding method, a chip-on-wafer bonding method, a chip-on-chip bonding method, or the like. The bonding structure BS may include a bonding pad, a bonding layer, a bonding interface, and the like. The bonding pad may include a metal such as copper and aluminum, and/or an alloy. The bonding interface may include a non-metal-non-metal interface, a metal-metal interface, or the like. The memory cell array CA and the peripheral circuit PC may be electrically connected by the bonding structure BS.

For reference, an interconnection structure included in the memory cell array CA and/or the peripheral circuit PC may be directly connected without a bonding pad. In an embodiment, a bonding layer included in the memory cell array CA and a bonding layer included in the peripheral circuit PC may be bonded to form a bonding interface, and the interconnection structure included in the memory cell array CA and the interconnection structure included in the peripheral circuit PC may be directly connected. Through this, contact plugs, lines, and the like formed on different wafers may be electrically connected without a separate bonding pad.

Other configurations may be equal or similar to those described above with reference to FIG. 21.

In further embodiments, the semiconductor device may have a structure in which the embodiments described above with reference to FIGS. 21 and 22 are combined or may have a partially modified structure. In the embodiment described with reference to FIGS. 21 and 22, positions of the memory cell array CA and the peripheral circuit PC may be changed. At least one memory cell array CA and/or at least one peripheral circuit PC may be additionally bonded to the embodiment described with reference to FIGS. 21 and 22. In an embodiment, a portion of the peripheral circuitry PC may be disposed in the memory cell array CA.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, changes, and combinations for the embodiments may be made by those skilled in the art, to which the present disclosure pertains, without departing from the technical idea of the present disclosure defined in the following claims, and it should be construed that these substitutions, modifications, changes, and combinations belong to the scope of the present disclosure.

What is claimed is:

1. A semiconductor device comprising:
a gate structure including alternately stacked conductive layers and first insulating layers;
a dummy stack adjacent to the gate structure in a first direction and including a first sidewall facing the gate structure, the first sidewall extending in a second direction along a length of the first sidewall and having a repeatedly nonplanar shape, wherein the second direction intersects the first direction; and
a second insulating layer located between the gate structure and the dummy stack,
wherein the dummy stack is located at a boundary of at least one component of the semiconductor device.

2. The semiconductor device of claim 1, wherein the dummy stack comprises:
a first stack including third insulating layers and fourth insulating layers that are alternately stacked and including the first sidewall; and
a second stack having a different width from the first stack, including fifth insulating layers and sixth insulating layers that are alternately stacked, and including a second sidewall facing the gate structure.

3. The semiconductor device of claim 2, wherein the second sidewall extends in the second direction along a length of the second sidewall, and deviates from the second direction in at least some regions.

4. The semiconductor device of claim 2, wherein the second sidewall extends in a straight shape along the second direction.

5. The semiconductor device of claim 1, further comprising:
a memory cell array including the gate structure and the dummy stack;
a peripheral circuit; and
a bonding structure electrically connecting the memory cell array and the peripheral circuit to each other.

6. The semiconductor device of claim 1, wherein the boundary of the at least one component of the semiconductor device comprises at least one of a boundary between adjacent memory blocks, a boundary between adjacent memory planes, or an edge of a chip.

7. A semiconductor device comprising:
a first gate structure including alternately stacked first conductive layers and first insulating layers;
a second gate structure adjacent to the first gate structure in a first direction and including alternately stacked second conductive layers and second insulating layers;
a dummy stack located between the first gate structure and the second gate structure, and including alternately stacked third insulating layers and fourth insulating layers, and including a first sidewall facing the first gate structure, the first sidewall extending in a second direction along a length of the first sidewall and deviating and extending from the second direction in some regions, wherein the second direction intersects the first direction;
a peripheral circuit; and
a bonding structure located between the peripheral circuit and the dummy stack.

8. The semiconductor device of claim 7, wherein the dummy stack includes a first stack having a first width and a second stack having a second width different from the first width,
the first stack includes the first sidewall, and
the second stack includes a second sidewall facing the first gate structure and extending in a straight shape along the second direction.

9. The semiconductor device of claim 8, wherein the first sidewall and the second sidewall are spaced apart from each other in the first direction.

10. The semiconductor device of claim 7, wherein the dummy stack includes a first stack having a first width and a second stack having a second width different from the first width,
the first stack includes the first sidewall, and
the second stack includes a second sidewall facing the first gate structure, extending in the second direction along a length of the second sidewall, and deviating and extending from the second direction in at least some regions.

11. The semiconductor device of claim 10, wherein the first sidewall includes a first convex portion and a first concave portion, and
the second sidewall includes a second convex portion disposed to correspond to the first convex portion and a second concave portion disposed to correspond to the first concave portion.

12. The semiconductor device of claim 10, wherein the first sidewall includes a first convex portion and a first concave portion, and
the second sidewall includes a second convex portion disposed to correspond to the first concave portion and a second concave portion disposed to correspond to the first convex portion.

13. The semiconductor device of claim 7, wherein the dummy stack includes a first stack having a first width and a second stack having a second width different from the first width,
the first stack includes a third sidewall extending in the second direction along a length of the third sidewall and deviating and extending from the second direction in some regions, and
the second stack includes a fourth sidewall facing the second gate structure and extending in a straight shape along the second direction.

14. The semiconductor device of claim 7, wherein the dummy stack includes a first stack having a first width and a second stack having a second width different from the first width,
the first stack includes a third sidewall extending in the second direction along a length of the third sidewall and deviating and extending from the second direction in some regions, and
the second stack includes a fourth sidewall facing the second gate structure, extending in the second direction along a length of the fourth sidewall, and deviating and extending from the second direction in some regions.

15. The semiconductor device of claim 7, wherein the first sidewall has a repeatedly bent shape.

16. The semiconductor device of claim 7, wherein the first sidewall has a repeatedly curved shape.
